(19) United States
(12) Patent Application Publication
(10) Pub. No.: US 2012/0242638 A1
(43) Pub. Date: Sep. 27, 2012

(54) DIELECTRIC SPACER FOR DISPLAY DEVICES

(75) Inventors: Fan Zhong, Fremont, CA (US); Yi Tao, San Jose, CA (US)

(73) Assignee: QUALCOMM MEMS TECHNOLOGIES, INC., San Diego, CA (US)

(21) Appl. No.: 13/071,394

(22) Filed: Mar. 24, 2011

(51) Int. Cl. G06F 3/038; H05K 3/30; G02B 26/00

(52) U.S. Cl. 345/211; 359/291; 359/290; 29/832

(57) ABSTRACT

This disclosure provides systems, methods and apparatus for forming spacers on a substrate and building an electromechanical device over the spacers and the substrate. In one aspect, a raised anchor area is formed over the spacer by adding layers that result in a high point above the substrate. The high point can protect the movable sections of the MEMS device from contact with a backplate.

### TECHNICAL FIELD

This disclosure relates to electromechanical systems and display devices. More particularly, this disclosure relates to the use of spacers within display devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

It is becoming desirable to manufacture display devices that can withstand increased external pressures. For example, some display devices, such as touchscreens, are designed to withstand pressure from, for example, a stylus or a user's finger. Unfortunately, touching the display device can result in deformation of the substrate (e.g., bending or buckling), which may lead to the substrate contacting the backplate and thereby damaging the display components, such as interferometric modulators.

### SUMMARY

The systems, methods and devices of the disclosure each have several innovative aspects, no single one of which is solely responsible for the desirable attributes disclosed herein.

One innovative aspect of the subject matter described in this disclosure can be implemented in an electromechanical device package. The electromechanical device package can include a substrate. A plurality of anchor regions can be disposed on the substrate. The anchor regions can include raised spacers. A plurality of electromechanical devices can be formed on the substrate. The electromechanical devices can be formed over the raised spacers and anchored to the substrate at the anchor regions. The electromechanical device package can include a backplate sealed to the substrate to form a package. The highest points of the electromechanical devices above the substrate can be located above the raised spacers. In one aspect, the electromechanical devices can be interferometric modulators. In one aspect, the spacers can be formed over a black mask layer in the anchor region. In one aspect, the black mask layer can be electrically conductive. In one aspect, the substrate can be a transparent substrate.

Another innovative aspect of the subject matter described in this disclosure can be implemented in an electromechanical device. The electromechanical device can include a substrate, an anchor region formed on the substrate, a means for spacing the anchoring means from the substrate, and a movable layer formed over the spacing means and anchored to the anchor region. In one aspect, the means for spacing can be formed over a black mask layer in the anchor region. In one aspect, the means for spacing can include raised dielectric structures. In one aspect, a high point above the substrate can be formed above the means for spacing.

Another innovative aspect of the subject matter described in this disclosure can be implemented in a method of fabricating an electromechanical system device. The method can include providing a substrate, forming an anchor region on the substrate, forming a spacer on the anchor region, and forming an electromechanical device anchored to the spacer in the anchor region. The electromechanical device can be formed after forming the spacer. In one aspect, the spacer can be a dielectric spacer. In one aspect, the anchor region can include a black mask layer. In one aspect, the method can form a highest point of the electromechanical device relative to the substrate above the spacer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a cross-section of an electromechanical display package.

FIG. 10 shows an example process of manufacturing an electromechanical device with built-in spacers or stand-off structures.

FIG. 11 shows an example plan view schematic illustration of a portion of interferometric modulator device including an array of pixels having built-in spacers or stand-off structures.

FIG. 12 shows an example of a partial cross-section of an interferometric modulator array with built-in spacers or stand-off structures taken along the line 11A-11A.

FIGS. 13A-13P show examples of cross-sectional schematic illustrations of various stages in a method of making an interferometric modulator array with built-in spacers or stand-off structures.

FIGS. 14A and 14B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

In some implementations, a display device can include electromechanical components such as movable mirrors, configured to reflect light (e.g., to a user). These electromechanical components are particularly susceptible to damage from external pressure. Accordingly, in some implementations, the display device is provided with internal spacers configured to prevent a backplate from contacting the sensitive electromechanical components. In some implementations, the electromechanical components are movable mirrors and include a movable layer that is anchored to the substrate at the corners of each pixel. The movable layer may be anchored to a black mask layer disposed on the substrate. In some implementations, a spacer is built at or near the center of at least one of these anchor areas, and below the anchor layers of the display device. By inserting a spacer below the anchor point, the upper portion of the anchor is raised upwards and provides a high point within the device that can prevent the backplate from touching the sensitive, adjacent, movable mirror. Once the spacer layer is deposited, fabrication of the device can continue as normal; however the resultant structure has a high point above where the spacer is deposited. Using this structure, the areas of the display device above the spacers become the highest points above the substrate. In some implementations, some pixels in the array may not include spacers.

In some implementations, a via is used for electrically connecting a stationary electrode of the device to a portion of the black mask that is used to anchor the movable layer at a corner of a pixel. The via may be offset from the anchoring point of the movable layer at the corner of the pixel to allow room for the spacer. In some implementations, the via is not included in every portion of the black mask at each pixel corner. Rather, the via can be located periodically throughout an interferometric modulator device. In some other implementations, a via can be provided over a channel of the black mask extending from the first portion of the black mask toward the second portion along an edge of the pixel. In some implementations, the via need not be included over each channel of the black mask provided along an edge of a pixel. Rather, the via can be provided over certain black mask channels, such as over a channel along an edge shared by a high gap and a mid gap pixel, to reduce the total area of the black mask.

Particular implementations of the subject matter described in this disclosure can be implemented to realize one or more of the following potential advantages. Some implementations can provide increased strength and resilience from external forces. For example, display devices built using the disclosed technology may provide more robust touchscreens because the incorporated spacers would increase the durability of the device to constant finger pressure. Also, display devices of larger sizes may be possible. Portions of pixel arrays may be designed to contact a backplate without damaging the interferometric pixels. Further, in some implementations, fabricating a spacer near the start of the fabrication process can allow for a cost effective and efficient manufacturing process. In some implementations, the additional spacer structure is formed with only one additional mask step.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

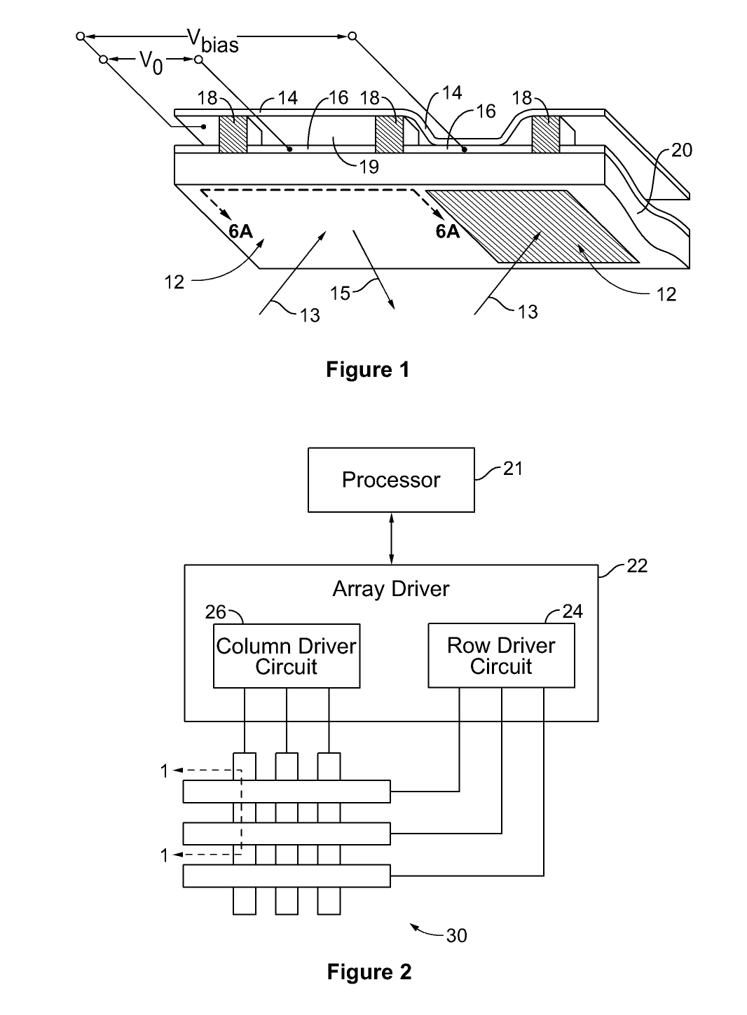

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

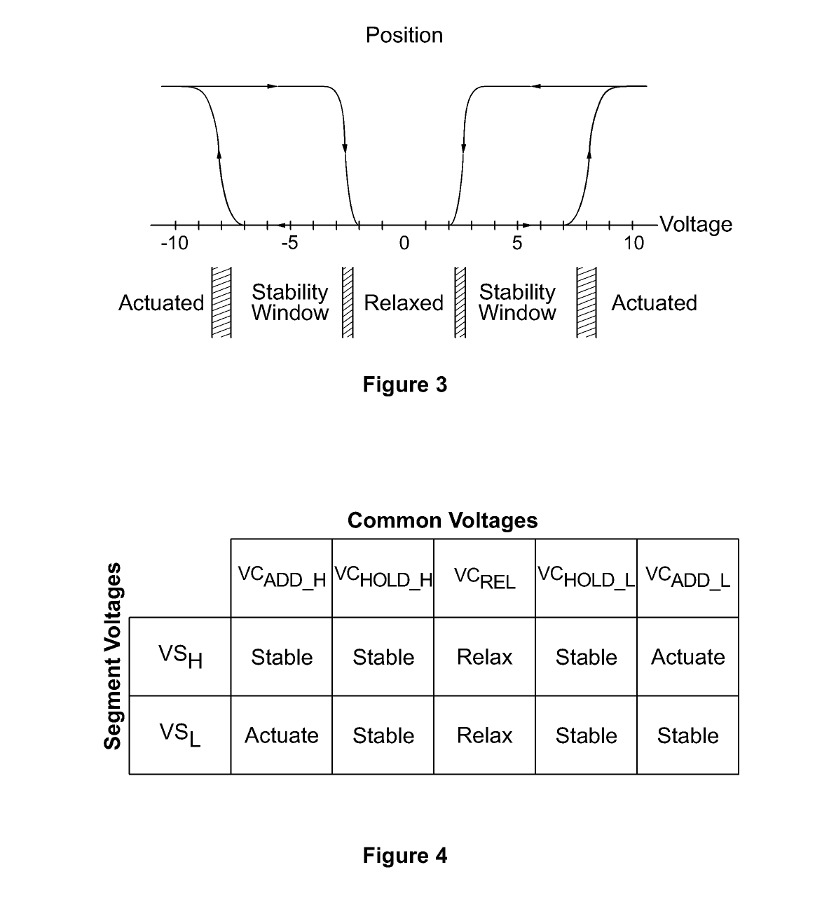

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

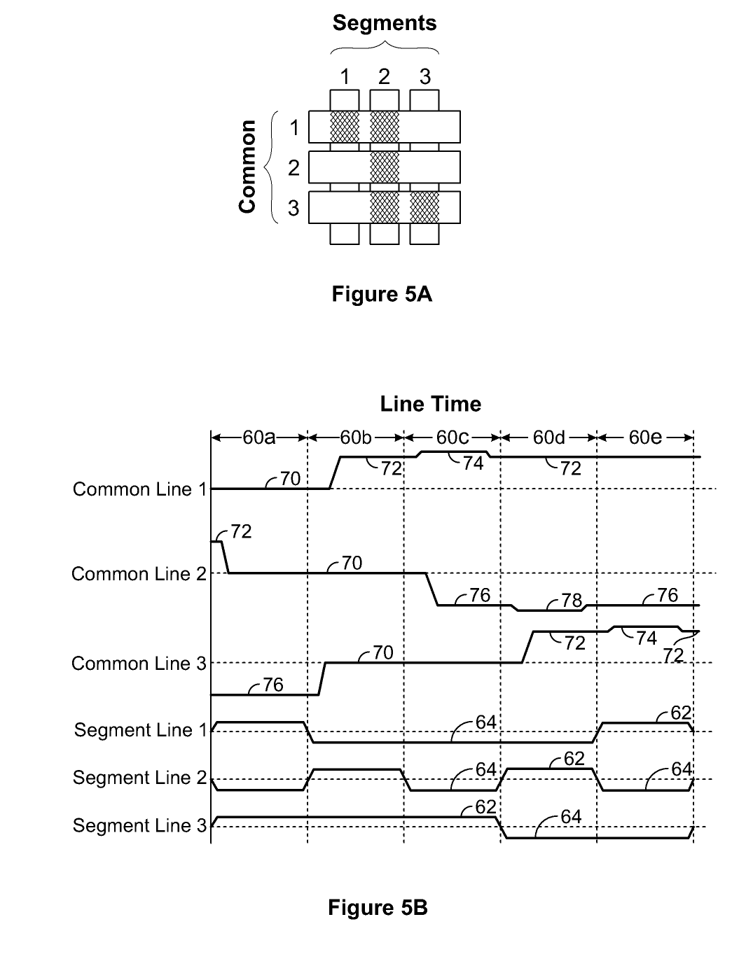

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

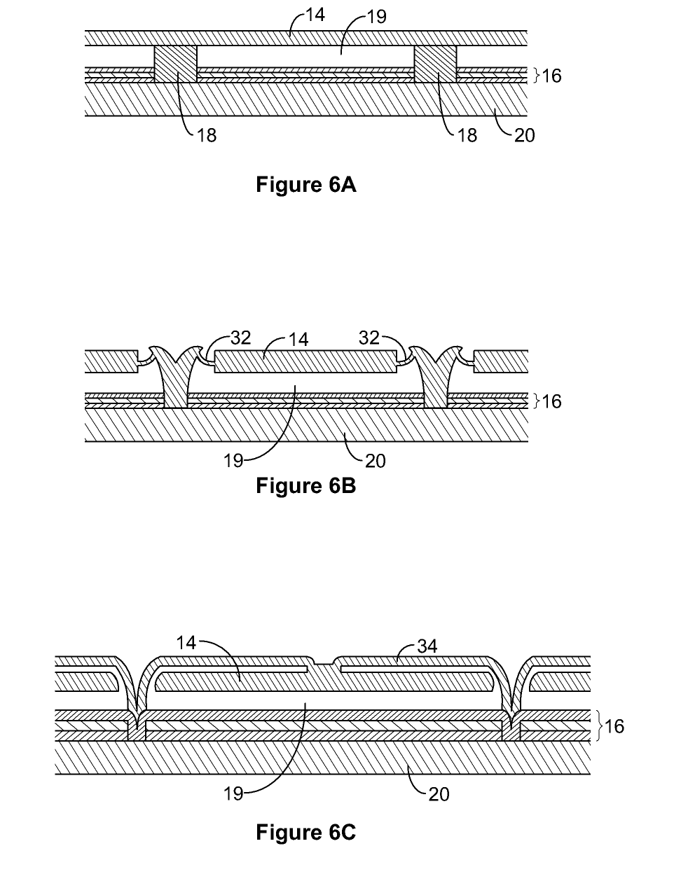

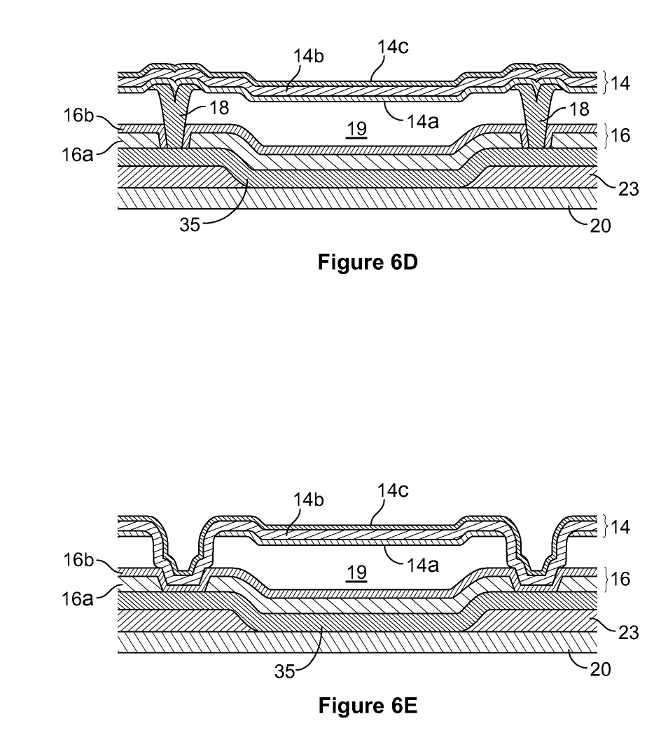

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., a portion of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive reflectors can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

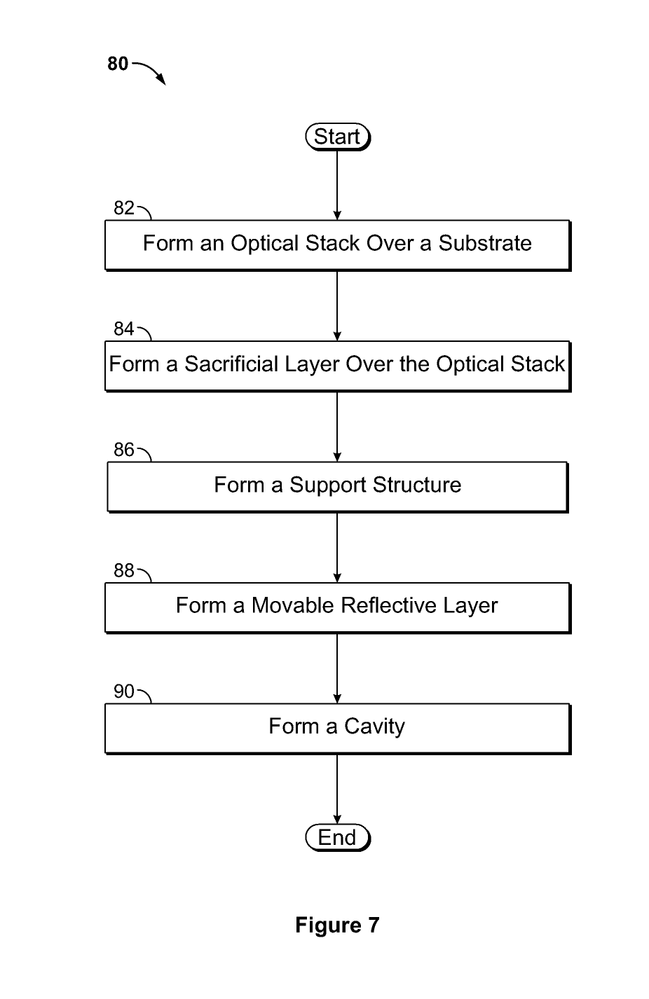

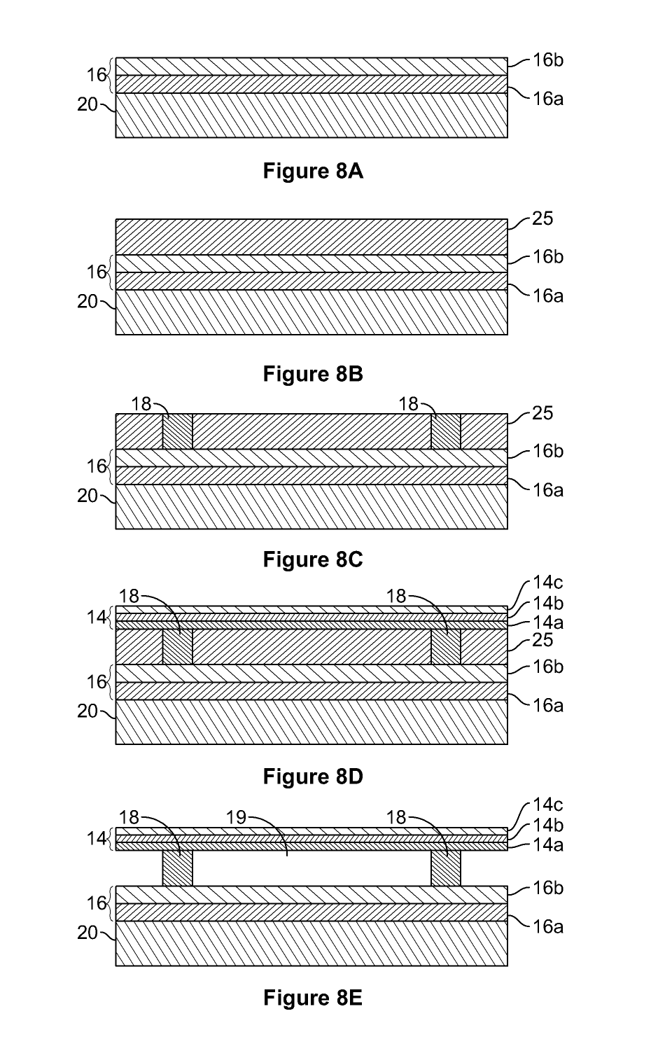

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning and removing portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or a-Si may be removed by dry chemical etching, e.g., by exposing the sacrificial layer 25 to a gaseous or vaporous etchant, such as vapors derived from XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Electromechanical Display with Spacer Structure

In some implementations, display devices having built-in spacers or stand-off structures are disclosed. Although the below description relates to interferometric display devices, it should be realized that any similar electromechanical display device also could incorporate the novel aspects of the disclosed technology by a person having ordinary skill in the art.

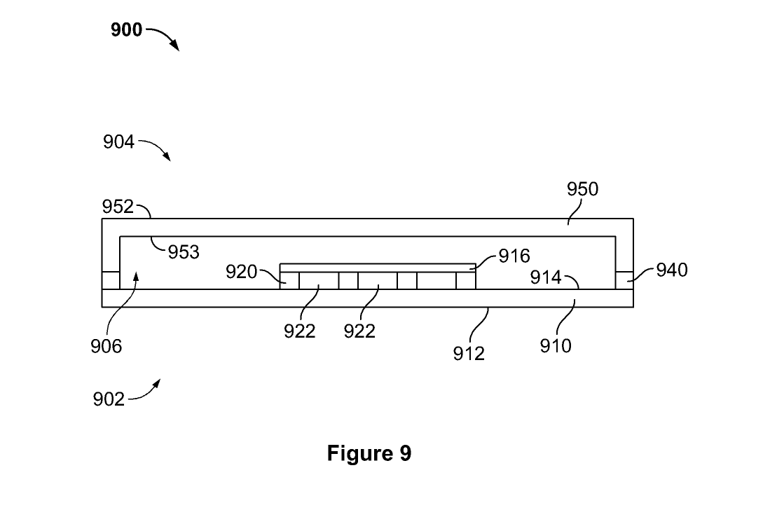

FIG. 9 shows an example of a cross-section of an electromechanical display package. The packaged electronic device 900 includes a substrate 910, an array 920 of interferometric modulators 922, a seal 940, and a backplate 950. The device 900 includes a bottom side 902 and a top side 904. The substrate 910 includes a lower surface 912 and an upper surface 914. On the upper surface 914 of the substrate the interferometric modulator array 920 is formed. In the illustrated implementation, the backplate 950 is secured to the substrate 910 by the seal 940. This forms a cavity 906 between the backplate 950 and the substrate 910.

The substrate 910 and interferometric modulators 922 are described in greater detail above. Briefly, the substrate 910 can be any substrate on which an interferometric modulator 922 is formable. In some implementations, the device 900 displays an image viewable from the lower side 902, and accordingly, the substrate 910 is substantially transparent or translucent. For example, in some implementations, the substrate is glass, silica, or alumina. The term “array glass” also may be used to describe the substrate 910. In some implementations, the first surface 912 of the substrate further includes one or more additional structures, for example, one or more structural, protective, or optical films as described below.

The interferometric modulators 922 include a mechanical layer 916 above the substrate 910 and below the backplate 950. In some implementations, portions of the mechanical layer 916 are susceptible to physical damage.

The backplate 950 also may be referred to herein as a “cap,” “backplane,” or “backglass.” These terms are not intended to limit the position of the backplate 950 within the device 900, or the orientation of the device 900 itself. In some implementations, the backplate 950 protects the array 920 from damage. Some implementations of an interferometric modulator 922 are potentially damaged by physical contacts. Consequently, in some implementations, the backplate 950 protects the array 920 from contact with foreign objects and/or other components in an apparatus including the array 920, for example. Furthermore, in some implementations, the backplate 950 protects the array 920 from other environmental conditions, for example, humidity, moisture, dust, changes in ambient pressure, and the like.

In implementations in which the device 900 displays an image viewable from the top side 904, the backplate 950 is substantially transparent and/or translucent. In some other implementations, the backplate 950 is not substantially transparent and/or translucent. In some implementations, the backplate 950 is made from a material that does not produce or outgas a volatile compound, for example, hydrocarbons, acids, amines, and the like. In some implementations, the backplate 950 is substantially impermeable to liquid water and/or water vapor. In some implementations, the backplate 950 is substantially impermeable to air and/or other gases. Suitable materials for the backplate 950 include, for example, metals, steel, stainless steel, brass, titanium, magnesium, aluminum, polymer resins, epoxies, polyamides, polyalkenes, polyesters, polysulfones, polystyrene, polyurethanes, polyacrylates, parylene, ceramics, glass, silica, alumina, and blends, copolymers, alloys, composites, and/or combinations thereof. Examples of suitable composite materials include composite films available from Vitex Systems (San Jose, Calif.). In some implementations, the backplate 950 further includes a reinforcement, for example, fibers and/or a fabric, for example, glass, metal, carbon, boron, carbon nanotubes, and the like.

In some implementations, the backplate 950 is substantially rigid. In some other implementations, the backplate 950 is flexible, for example, foil or film. In some implementations, the backplate 950 is deformed in a predetermined configuration before and/or during assembly of the packaged device 900.

With continuing reference to FIG. 9, the backplate 950 includes an inner surface 953 and an outer surface 952. In some implementations, the inner surface and/or outer surface of the backplate further include one or more additional structures, for example, a structural, protective, mechanical, and/or optical film or films.

In the implementation illustrated in FIG. 9, the backplate 950 is substantially planar. In some other implementations, the inner surface 953 of the backplate 950 may be recessed. A backplate with this configuration may be referred to as a “recessed cap” herein. Other implementations of a packaged device 900 may include a curved or bowed backplate 950. In some implementations, the backplate 950 is pre-formed into the curved configuration. In some other implementations, the curved shape of the backplate 950 is formed by bending or deforming a substantially flat precursor during assembly of the packaged device 900. For example, in some implementations, an array 920 of interferometric modulators is formed on a substrate 910 as described above. A seal material, for example, a UV curable epoxy, is applied to the periphery of a substantially planar backplate 950, which is wider and/or longer than the substrate 910. The backplate 950 is deformed, for example, by compression, to the desired size, and positioned on the substrate 910. The epoxy is cured, for example, using UV radiation to form the seal 940.

In some implementations, the gap or headspace between the inner surface 953 of the backplate and the array 920 is about 10 μm. In some implementations, the gap is from about 30 μm to about 100 μm, for example, about 40 μm, 50 μm, 60 μm, 70 μm, 80 80 μm, or 90 μm. In some implementations the gap can be at greater than about 100 μm, for example, about 300 μm, about 0.5 mm, about 1 mm, or greater. In some implementations, the gap or headspace between the inner surface 953 of the backplate and the array 920 is not constant.

In some other implementations, forces likely to be encountered in normal use of the device 900 are sufficient to cause the array 920 to contact the backplate 950, typically, at or near the center of the backplate 950 and array 920. For example, one of skill in the art will understand that, all other things remaining equal, as the length and/or width of the device 900 increase the relative movement between the array 920 and backplate 950 will also increase. The length and/or width of a device 900 will increase, for example, with increasing size and/or number of the interferometric modulators 922 in the array 920. At some point, a force likely to be encountered in the normal use of the device 900 will induce a relative motion that will cause some part of the array 920 to contact the backplate 950, thereby potentially damaging one or more of the interferometric modulators 922 in the device.

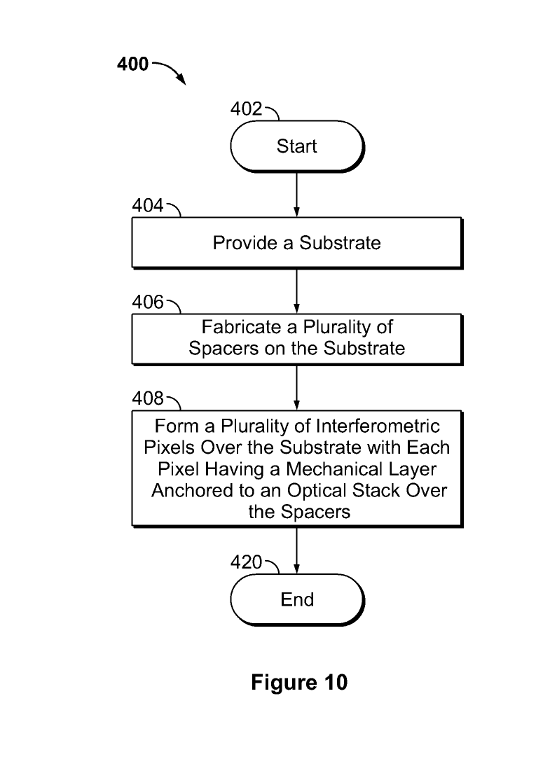

FIG. 10 shows an example process 400 of manufacturing an electromechanical device with built-in spacers or stand-off structures. The process starts at block 402. As shown in block 404 the process begins by providing a substrate. The process continues in block 406 by fabricating a plurality of spacers on the substrate. The spacers may be formed with a dielectric material by depositing the dielectric material on the substrate and etching the material into the desired shape. The process 400 continues in block 408 by forming an electromechanical device anchored to the spacer, wherein the electromechanical device is formed after forming the spacer. The process ends at block 420.

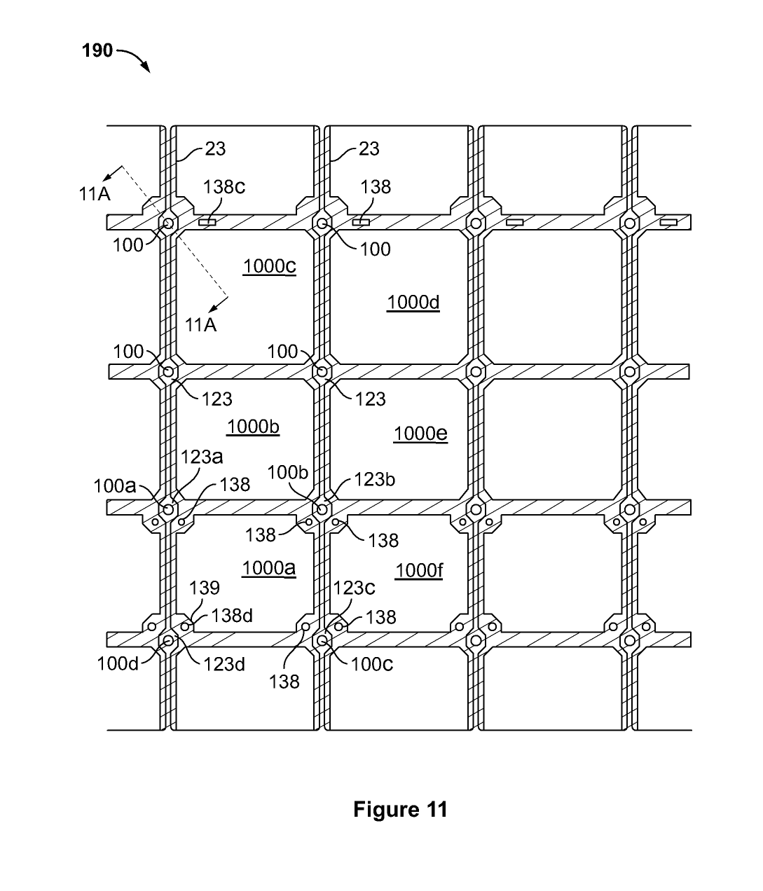

FIG. 11 shows an example of a plan view schematic illustration of a portion of interferometric modulator device including an array of pixels having built-in spacers or stand-off structures. The illustrated interferometric modulator device 190 includes an array of pixels, for example, pixels 1000a-1000f.

As shown in FIG. 11, the pixels 1000a-1000f are roughly square shaped and include an electrically conductive black mask 23 disposed along at least a portion of each edge. In the implementations illustrated in FIG. 11, the black mask 23 circumscribes each pixel. Although not illustrated to improve figure clarity, the black mask 23 has been provided over a substrate, a dielectric layer has been provided over the black mask 23, and an optical stack, including a stationary electrode, has been provided over the dielectric layer. The process for forming such an array will be detailed later.

In the implementation illustrated, spacers 100 are provided at or near each corner of pixel. The spacers 100 are provided over the black mask 23. As shown in FIG. 11, for example, spacers 100a-100d are provided in each corner of pixel 1000a. In some implementations, a spacer 100 is located in only one corner, or in two corners, or in three corners of pixel. Further, the some implementations, a pixel may not include spacers 100. As will be described below, the highest points above the substrate of the interferometric modulator device array 190 can be located over the spacers 100.

A mechanical layer, not shown to improve figure quality, is positioned over the optical stack to define a gap height of the pixel. The gap height can vary across pixels. The mechanical layer is anchored to the optical stack over the spacers 100 at the corners of each pixel. For example, the mechanical layer of pixel 1000a is anchored at or near the four corners of the pixel over the first, second, third, and forth spacers 100a, 100b, 100c, and 100d, and results in raised corner areas 123a, 123b, 123c, and 123d, respectively, adjacent to the spacers. As described earlier, the mechanical layer can be anchored over the spacers 100 in a multitude of ways. By anchoring the mechanical layer over the spacers 100, high points above the array are formed. In addition, by providing the spacers over the black mask, the black mask 23 can absorb light in the optically inactive regions, for example, regions under and around the spacers 100, raised corner areas 123, and areas that bend during actuation.

As shown in FIG. 11, in some implementations, vias 138 may be placed slightly offset from the corner of a pixel. The vias 138 are used to electrically contact the stationary electrode of the optical stack to various portions of the black mask 23. Increased portions or bulges of black mask can be provided to mask the optically inactive via 138. For example, black mask bulge 139 may be provided for corner via 138d.

In some implementations, vias 138 may be placed along the black mask channels along the pixel edges. For example, as illustrated in FIG. 11, via 138c is provided along a black mask channel of pixel 1000c. In some implementations, vias 138 are not included over each channel of the black mask provided along an edge of each pixel. Rather, the vias 138 can be provided over certain black mask channels, such as over a channel along an edge shared by a high gap and a mid gap pixel, to reduce the total area of the black mask.

In some implementations (not shown), a via 138 may be placed in a corner of pixel that does not have a spacer 100 (i.e., in the area where the spacer 100 is located). In some implementations, vias 138 can be included over portions of the black mask 23 at corners of pixels of the largest gap size. Positioning the vias 138 near the portions of the black mask 23 at corners of pixels of the largest gap size can improve performance because high gap pixels can have a larger bending region in the actuated state. Thus, the relatively large optically inactive area results in a larger black mask area that can provide additional space for the via 138.

The area of black mask 23 around spacers 100, vias 138, and anchoring regions may vary in size for each pixel. For example, the amount of black mask 23 surrounding an anchor area can be larger for pixels of the largest gap size, so as to account for increased mechanical layer bending during activation.

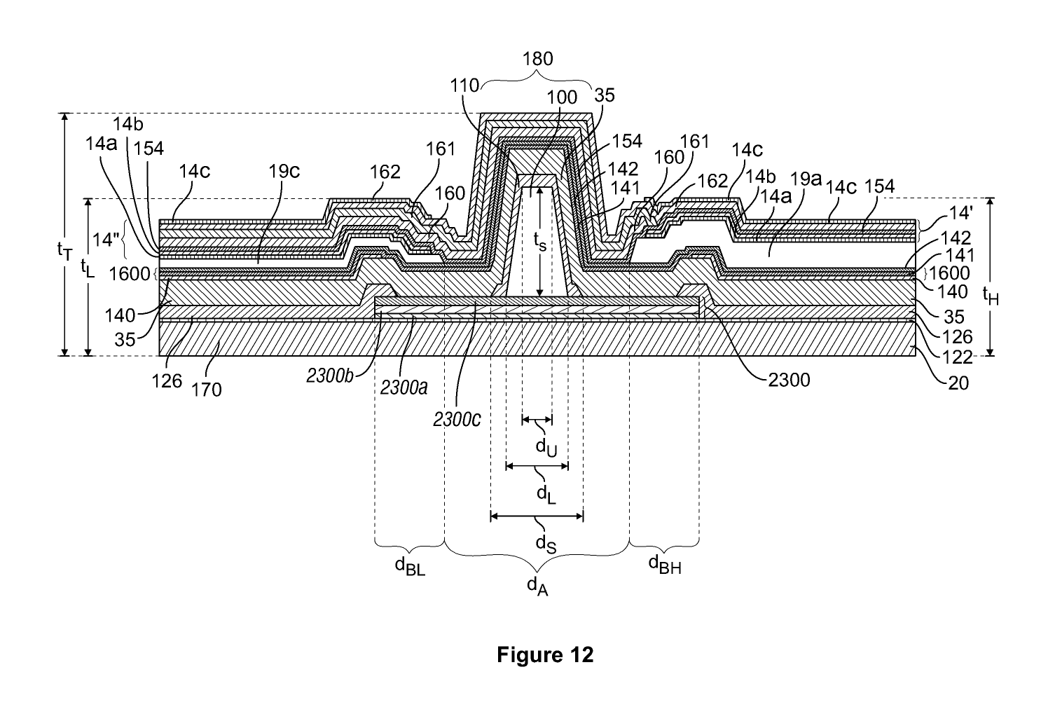

FIG. 12 shows an example of a partial cross-section of an interferometric modulator array with built-in spacers or stand-off structures taken along the line 11A-11A. The cross-section illustrates a spacer 100 positioned between a modulator including a low gap 19c and a modulator including a high gap 19a. The modulators each include a mechanical layer anchored to an optical stack 16. The mechanical layer is anchored to the optical stack 16 at least in part by support layers 160-162 that span between the modulators and cover the spacer 100 located in between the modulators. This anchor region can be roughly depicted as anchor area d_{A}. Anchoring the mechanical layer in this manner can result in a raised anchor area.

The spacer 100 can be located at or near the center of the anchor region d_{A}. Building a spacer 100 in this area allows for the modulators to be built in a straightforward manner but results in a high section 180 of the modulator array located over the spacer 100. This high section 180 can contact a backplate above (not shown) without damaging the interferometric modulator array. Further, the high sections 180 can prevent a backplate from contacting, and thus damaging, the movable sections of the array.

Detailing FIG. 12, the interferometric modulator array can be built atop an etch stop layer 122 disposed over a substrate 20. A black mask 23 can be disposed over optically inactive portions of the etch stop layer 122. The black mask 23 can be configured to absorb light. Optically inactive regions of the array include, for example, regions around the anchor area d_{A}, and regions around bending portions of the mechanical layer, for example, the low gap and high gap bending areas d_{BL} and d_{BH}. As illustrated, the black mask 23 layer includes an optical absorber layer 23a, a dielectric sublayer 23b, and a bussing layer 23c.

A spacer 100 is disposed over and at or near the center of the black mask 23. In the implementation illustrated in FIG. 12, the spacer 100 is roughly shaped as a truncated cone, such that the spacer 100 is roughly trapezoidal shaped when viewed from the side and roughly circular when viewed from above. However, the spacer 100 may be any suitable shape, including but not limited to, cube, frustum, trapezoidal prism, pyramid, cylinder, or any suitable three dimensional shape formed by a generatrix.

The spacer 100, when viewed from the side, may include a height tₛ, a lower diameter d_{L}, and an upper diameter d_{U}. In some implementations, the spacer 100 can have, for example, a height tₛ in the range of about 0.5-2 μm, a lower diameter d_{L} in the range of about 2-4 μm, and an upper diameter d_{U} in the range of about 1.5-3.5 μm. In some implementations the spacer 100 has a height of about 1 μm with a lower diameter d_{L} of about 3 μm, and an upper diameter d_{U} of about 2.5 μm.

Additional spacer structure 110 can be formed over and around the spacer by disposing and patterning a shaping structure 126. The addition spacer structure 110 can effectively enlarge the lower diameter of the spacer dₛ. In some implementations, the lower diameter of the spacer dₛ is increased, for example, to a range of about 2.1-5 μm, for example about 3.2 μm.

The modulators can be built by disposing a shaping structure 126 over a portion of the black mask 23 and over the etch stop layer 122 in optically active regions of the array. A dielectric layer 35 is disposed over the shaping structure 126, black mask 23, and additional spacer structure 110.

An optical stack 16 can be built on the dielectric layer 35 in areas over the shaping structure 126. In the implementation illustrated in FIG. 12, the optical stack 16 includes stationary electrode layer 140, a transparent dielectric layer 141, and a dielectric protection layer 142. A dielectric protection layer 142 can be disposed over the optical stack 16 and over the optically inactive regions.

Portions of the mechanical layer, as shown in FIG. 12, can be disposed over the modulators and the spacer 100, and anchored to the optical stack 16 over and adjacent to the spacer 100. For example, support layers 160-162 can span the low gap 19c and high gap 19b and envelope the spacer 100 located in between the gaps. The support layers 160-162 also can form portions of the mechanical layers. The mechanical layers may not be uniform in construction. In the illustrated implementation, for example, the mechanical layer over the high gap modulator 14′ includes a reflective layer 14a, a support layer 14b, an etch-stop layer 154, a third support layer 162, and a cap layer 14c, while the mechanical layer over the low gap modulator 14″ includes a reflective layer 14a, a support layer 14b, an etch-stop layer 154, the first support layer 160, a second support layer 161, a third support layer 162, and a cap layer 14c, while the portion of the mechanical layer covering the spacer and anchoring it to the optical stack includes the first, second, and third support layers 160-162.

Fabricating the spacer 100 in the anchor area and below the support layers 160-162, results in a high section 180 with a height above the substrate t_{T} greater than both the total height of the high gap modulator above the substrate t_{H} and the total height of the low gap modulator above the substrate t_{L}. In some implementations, the high gap modulator has a height above the substrate t_{H} ranging from about 1,400-1,500 nm, for example, about 1,470 nm, while the low gap modulator has a height above the substrate t_{L} ranging from about 1,300-1,450 nm, for example, about 1,400 nm. In some implementations, the high section 180 has a height above the substrate t_{T} ranging from about 1,000-3,000 nm, for example, about 1,900 nm.

The interferometric modulator array can be packaged by a backplate (not shown) as described above. The high sections 180 of the interferometric modulator can contact the backplate, thereby preventing damage to the modulators in the array.

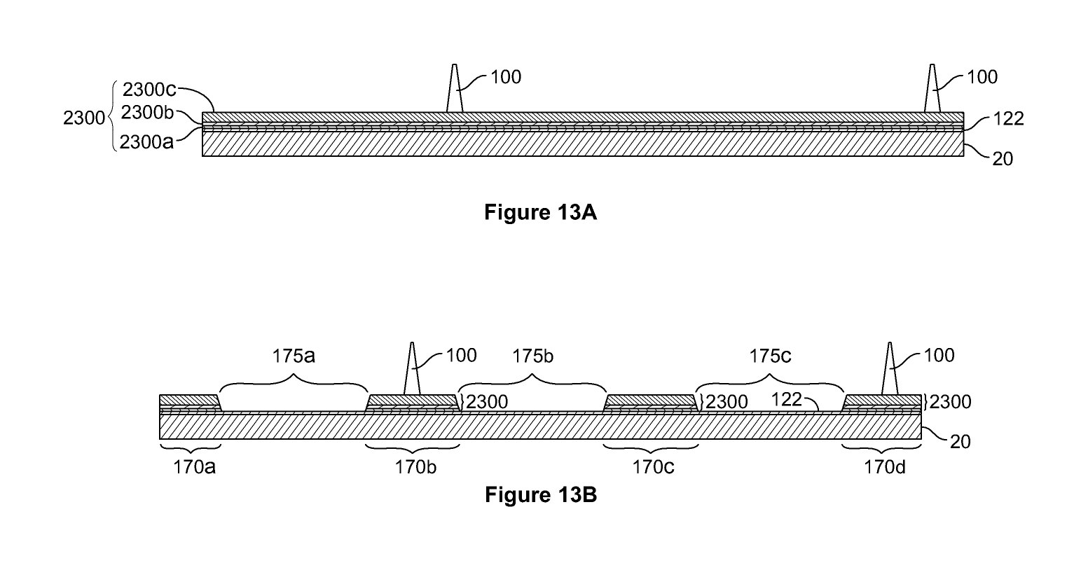

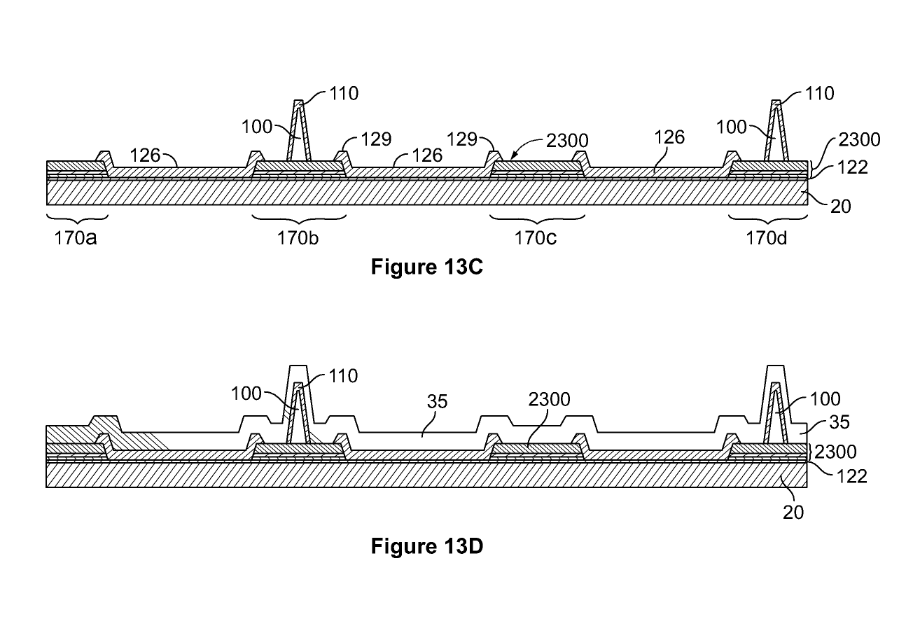

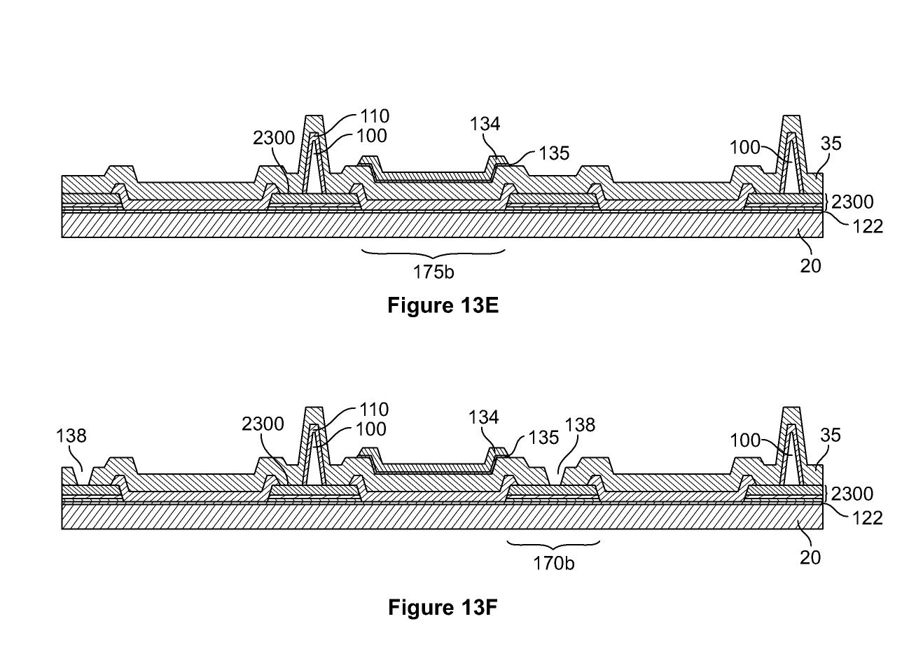

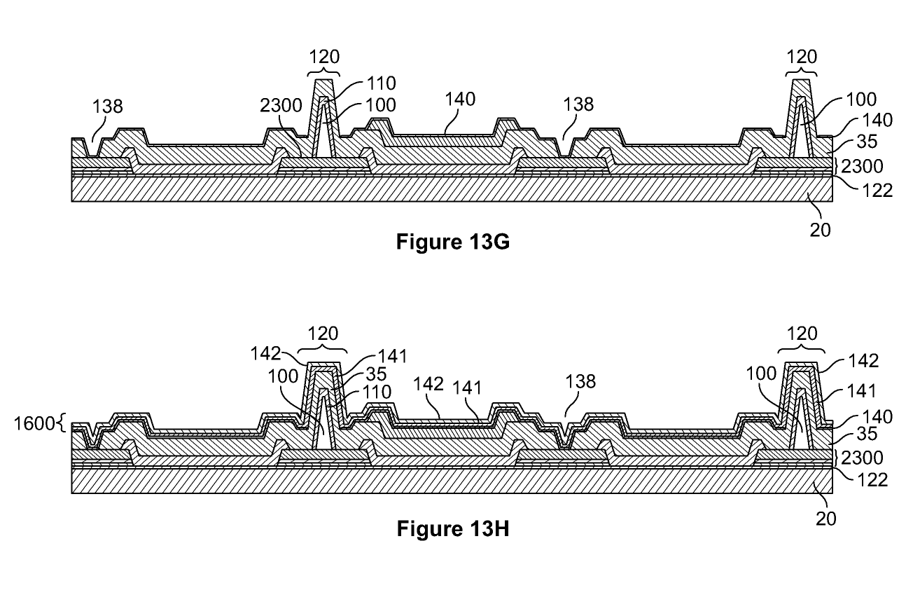

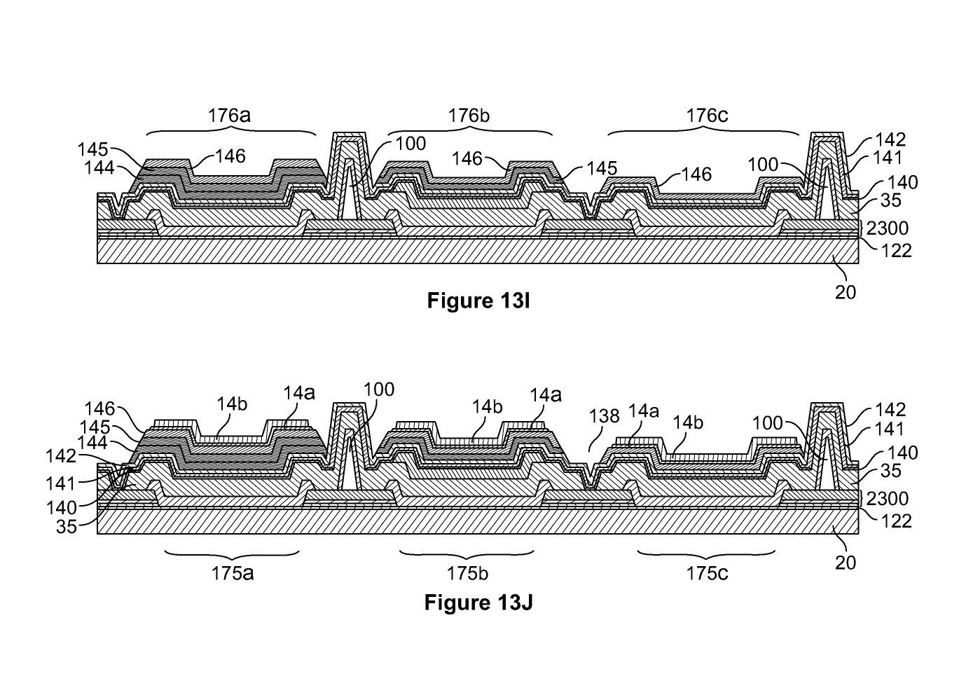

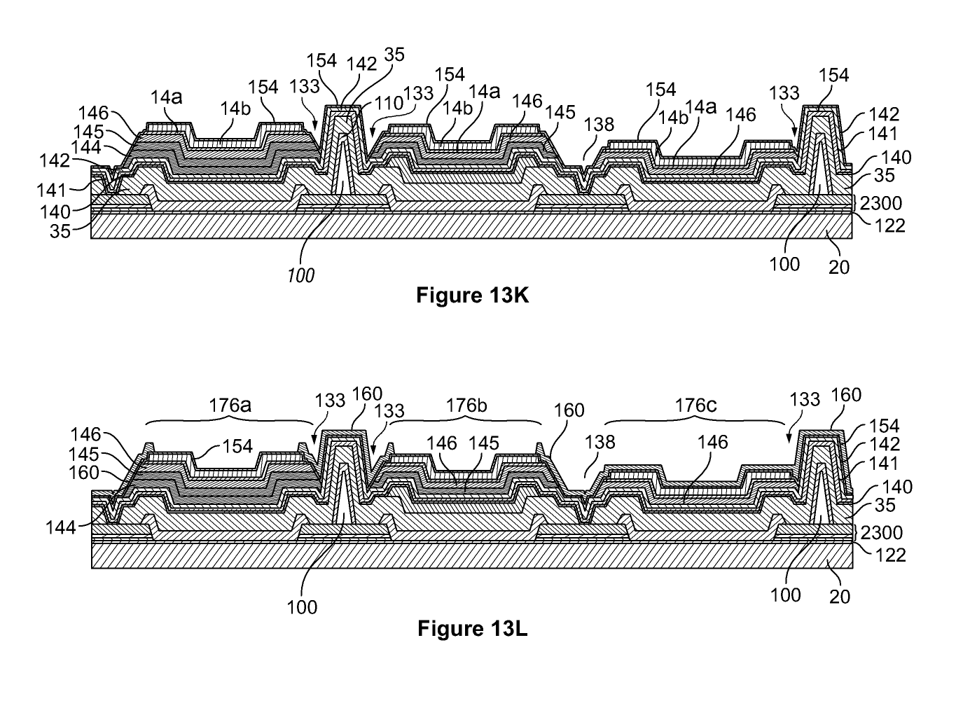

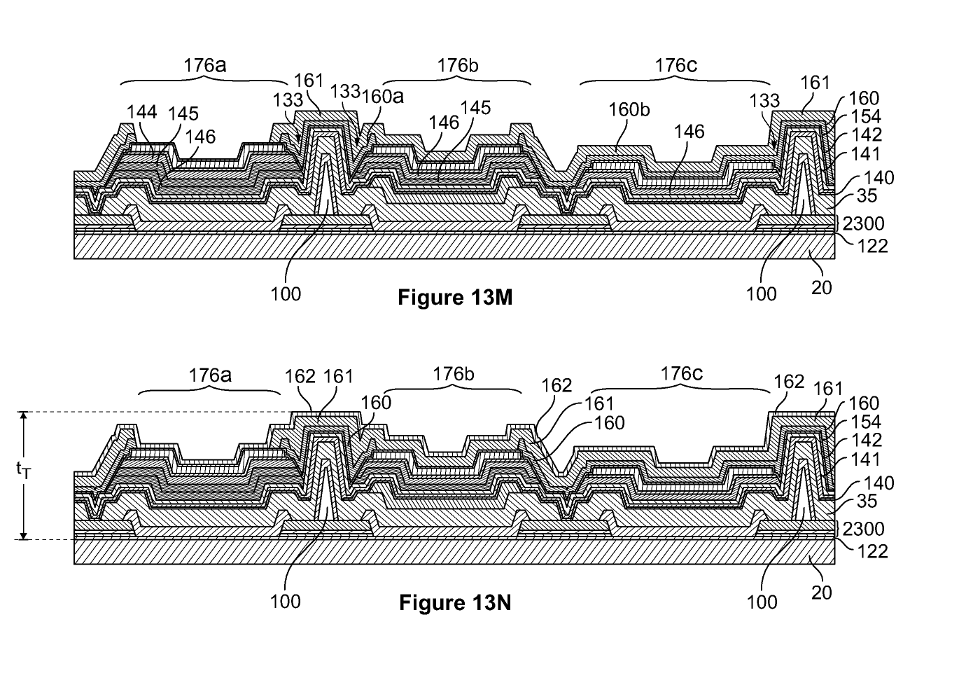

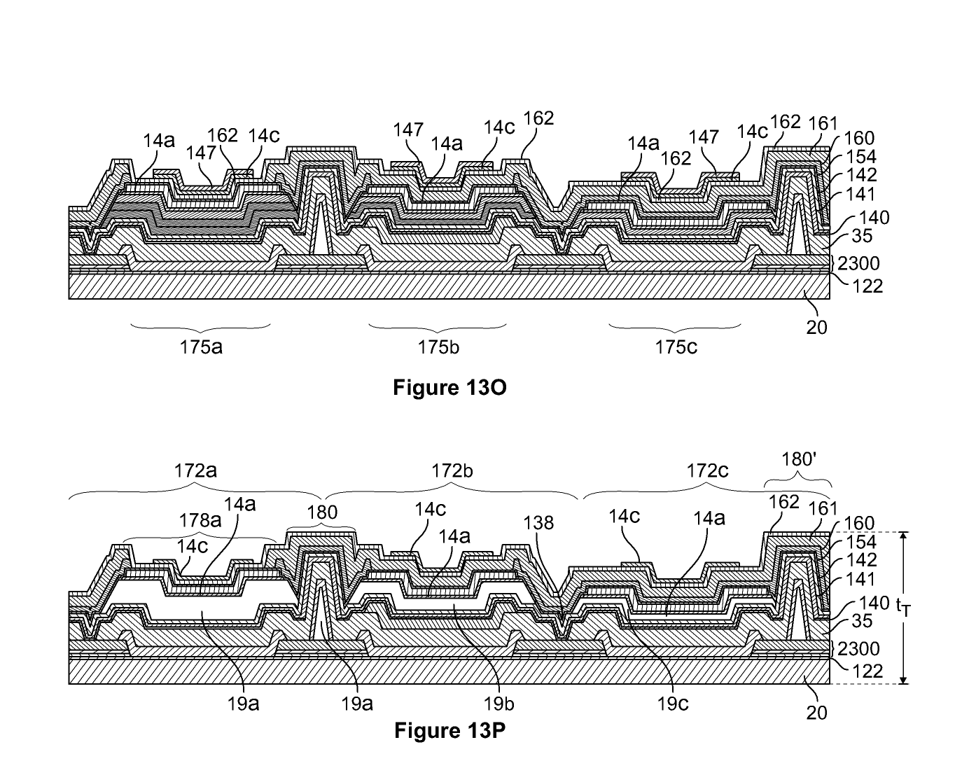

FIGS. 13A-13P show examples of cross-sectional schematic illustrations of various stages in a method of making an interferometric modulator array with built-in spacers or stand-off structures.

In FIG. 13A, a black mask structure 2300 and a plurality of spacers 100 have been formed over a substrate 20. As shown, the device has been fabricated by layering a first etch stop layer 122 on top of the substrate 20. The etch stop layer 122 may include Aluminum Oxide (AlOx) or any other well known etch stop composition. In some implementations, the etch-stop layer 122 is an AlOx layer having a thickness in the range of about 50-250 Å, for example, about 160 Å.

On top of the etch stop layer 122 is a black mask layer 2300 which is fabricated from a series of sublayers. The first sublayer is an optical absorber sublayer 2300a, which may include a MoCr layer. In some implementations, the optical absorber sublayer 2300a includes a MoCr layer having a thickness in the range of about 30-80 Å, for example, about 50 Å.

Layered on top of the optical absorber sublayer 2300a is a dielectric sublayer 2300b, which may include SiO₂. In some implementations, the optical absorber sublayer 2300a includes a SiO₂ layer having a thickness in the range of about 500-1,000 Å, for example, about 750 Å. Layered on top of the dielectric sublayer 2300b is a bussing sublayer 2300c which may include an aluminum alloy such as aluminum silicon (AlSi). In some implementations, the bussing sublayer 2300a includes an AlSi layer having a thickness in the range of about 100-6,000 Å, for example, about 500 Å.

Formed on top of the black mask layer 2300 is a spacer 100. In some implementations, not shown, the spacer 100 is not formed on top of a black mask layer 2300, but rather formed on the substrate 20 or on the etch stop layer 122. The spacer 100 can be formed by a variety of techniques known to those of skill in the art including photolithography and dry etching. The spacer 100 can be formed with any suitable dielectric material well known in the art. The spacer 100 can include, for example, SiO₂, SiON, or silicon nitride (Si₃N₄). In some implementations, the spacer 100 is formed by depositing a SiO₂ layer, masking the desired pattern, and etching the SiO₂ layer in the desired shape. In some implementations, the spacer 100 includes a SiO₂ layer having a thickness in the range of about 0.5-4 μm, for example, about 1 μm. The etching process can include CF₄ and/or O₂.

As shown in FIG. 13B, the process continues by masking and etching of the black mask layer 2300 to provide the optically active sections 175a-175c. The etching process can include CF₄ and/or O₂ for the MoCr and SiO₂ layers and Cl₂ and/or BCl₃ for the aluminum alloy layer. The optically active sections can provide the area for fabrication of the interferometric modulators, while the remaining black mask areas 170a-170d can be used to mask optically inactive regions such as anchor regions and/or bending between modulators.

The remaining black mask areas 170a-170d may be of varying sizes. For example, larger remaining black mask areas may be used between modulators having larger gap sizes to account for additional bending of the mechanical layer. In operation, when the mechanical layer is actuated, the portions of the mechanical layer aligned in a plane above the optical stack, contact the optical stack. However, a portion of the mechanical layer (e.g. along edges of a pixel) may not contact the optical stack. These portions of the mechanical layer, not in contact with the optical stack, can interferometrically produce undesired colors if additional black mask area is not provided. This portion of the mechanical layer out of contact with the optical stack during actuation can increase for pixels having larger gap heights. The bending region of the high gap pixel can be greater than that of the low gap pixel, because the gap is larger. Accordingly, additional areas of black mask around the anchoring region can be provided for pixels with larger gap sizes to mask the portions of the mechanical layer that may bend during actuation.

In FIG. 13C, the process continues by forming a shaping structure 126 and additional spacer structure 110. The shaping structure 126 and additional spacer structure 110 can be formed by depositing a buffer oxide layer over the interferometric modulator and etching away a portion of the layer adjacent the spacers 100 and above the black mask layers 23. In some implementations, the buffer oxide layer includes a SiO₂ layer having a thickness in the range of about 500-6,000 Å, for example, about 1,000 Å. The etching process can include CF₄ and/or O₂.

The shaping structure 126 can aid in maintaining a relatively planar profile across the substrate by filling in gaps between remaining black mask areas 170a-170d. The shaping structure 126 also can overlap a portion of the remaining black mask areas 170a-170d. For example, as illustrated in FIG. 13C, the shaping structure 126 can overlap remaining black mask areas 170a-170d to form protrusions 129. The protrusions 129 can aid in forming a kink in the mechanical layer to be formed above. In particular, one or more layers, including the mechanical layer, can be deposited over the shaping structure 126, thereby substantially replicating one or more geometric features of the shaping structure 126. This process can produce an upwardly extending wave or kink in a subsequently deposited conformal layer, such as a mechanical layer. Although the various electromechanical systems and devices illustrated herein are shown and described as including the shaping structure 126, persons having ordinary skill in the art will recognize that the methods of forming a mechanical layer as described herein can be applicable to processes lacking the shaping structure 126.

The additional spacer structure 110 can effectively increase the size of the spacer 100. However, the overall effect of the buffer oxide layer on effective spacer size depends on the shape of the original spacer. For example, one skilled in the art will recognize that more material will be deposited on surfaces that are more exposed to the deposition instrument. As shown for example in FIG. 13C, more buffer oxide layer is deposited on the top surface of the spacer 100 than the sides of the spacer 100 because of the selected spacer 100 geometry.

In FIG. 13D, the process continues by providing a dielectric layer 35 over the interferometric modulator array with built-in spacers. The dielectric layer 35 can include, for example, SiO₂, SiON, and/or tetraethyl orthosilicate (TEOS) or other suitable materials well known in the art. In some implementations, the dielectric layer 35, includes a SiO₂ layer having a thickness in the range of about 3,000-6,000 Å, for example, about 4,000 Å. However, the dielectric layer 35 can have a variety of thicknesses depending on the desired optical properties.

In FIG. 13E, the process continues by forming a color enhancement structure 134. The color enhancement structure 134 can be selectively provided for certain interferometric modulators. For example, in a multi-color interferometric modulator implementation employing multiple gap heights, the color enhancement structure 134 can be provided over modulators having a particular gap size. In the implementation illustrated in FIG. 13E, a color enhancement structure 134 is provided for what will become a mid gap interferometric modulator.

One or more layers can be provided on the dielectric layer 35 before providing the color enhancement structure 134. For example, as shown in FIG. 13E, an etch-stop layer 135 is provided before providing the color enhancement layer 134. The etch stop layer can include AlOx or any other well known etch stop composition. The etch stop layer 135 can be formed by depositing an AlOx layer on the dielectric layer 35 and etching the layer such that the etch stop layer 135 remains atop the dielectric layer 35 in the area above optically active section 175b. In some implementations, the etch stop layer 135 includes an AlOx layer having a thickness in the range of about 50-250 Å, for example, about 160 Å. The etch process to remove the AlOx can include phosphoric acid (H₃PO₄).

Similarly, in some implementations, the color enhancement structure 134 is provided by depositing a SiON layer on the etch stop layer 135 and etching the layer such that the color enhancement structure 134 remains atop the etch stop layer 135 in the area above optically active section 175b. In some implementations, the color enhancement structure 134 includes a SiON layer having a thickness in the range of about 1,500-2,500 Å, for example, about 1,900 Å. The etch process to remove the SiON can include CF₄ and/or O₂.

In FIG. 13F, the process continues by forming a via 138 in the dielectric layer 35 by etching a portion of the dielectric layer 35. The via 138 can permit a subsequently deposited layer to contact the black mask structure 23. In some implementations, the via 138 can electrically connect a stationary electrode to the black mask 23. As shown in FIG. 13F, vias need not be included over each region of the black mask 23. Rather, vias can be placed periodically in the interferometric modulator so as to increase the fill factor of the array. For example, as shown in FIG. 13F, a via 138 has been included over black mask portion 170b in between the second or mid gap and third or low gap pixel. The vias, can have a variety of shape and sizes. For example, the vias can be shaped as a circle, oval, octagon and/or any other suitable shape. The size of the vias can vary with process. In some implementations, each via 138 has a largest width in the range of about 1.5-3.0 μm, for example, about 2.4 μm.

In FIGS. 13G-13H, the process continues by forming an optical stack in the optically active regions of the interferometric modulator array with built-in spacers. The optical stack can include a plurality of layers. The optical stack can be electrically conductive, partially transparent and partially reflective, and can include a stationary electrode for providing the electrostatic operation for the interferometric modulator device. In some implementations, some or all of the layers of the optical stack, including, for example, the stationary electrode, are patterned into parallel strips, and may form row electrodes in a display device.

In FIG. 13G a stationary electrode 140 is provided. As illustrated, the stationary electrode 140 is provided over the dielectric layer 35, color enhancement structure 134, and via 138, but not provided over the spacers 100. By providing the stationary electrode 140 over the via 138, for example, the via 138 can electrically connect the stationary electrode 140 to the black mask 23. The stationary electrode 140 can include MoCr or any other well known electrode composition. The stationary electrode 140 can be formed by depositing a MoCr layer and etching the layer such that stationary electrode 140 is removed from spacer area 120. In some implementations, the stationary electrode layer 140 includes a MoCr layer having a thickness in the range of about 30-80 Å, for example, about 50 Å. The etching process to remove the MoCr can include Cl₂ and/or O₂.

In FIG. 13H, a transparent dielectric layer 141 and a dielectric protection layer 142 are provided to complete the optical stack 1600. The transparent dielectric layer 141 may include any transparent dielectric material well known in the art. The transparent dielectric layer 141 can be formed by depositing a SiO₂ layer over the interferometric modulator array with built-in spacers. In some implementations, the transparent dielectric layer 141 includes a SiO₂ layer having a thickness in the range of about 50-500 Å, for example, about 330 Å.

The dielectric protection layer 142 can be provided over the transparent dielectric layer 141. The dielectric protection layer 142 can be formed from a variety of materials that are partially reflective such as various metals, semiconductors, and dielectrics. The dielectric protection layer 142 can protect the transparent dielectric layer 141 from the over etch attack of subsequent sacrificial layer etch processes and the attack from the final sacrificial layer removal process. In some implementations, the dielectric protection layer 142 includes an AlOₓ layer having a thickness in the range of about 50-150 Å, for example, about 100 Å. As shown in FIG. 13H, the transparent dielectric layer 141 and the dielectric protection layer 142 can cover the spacer areas 120.

In FIG. 13I, the process continues by providing a plurality of sacrificial layers over the optical stack 1600. The sacrificial layers are later removed to form a gap or cavity, as will be discussed below. The sacrificial layers may include Mo or a-Si or any other well known sacrificial composition.

The use of a plurality of sacrificial layers can aid in the formation of a display device having a multitude of resonant optical gaps. For example, as illustrated, various gap sizes can be created by selectively providing a first sacrificial layer 144, a second sacrificial layer 145, and a third sacrificial layer 146. This can provide a first gap size (or “high gap”) equal to about a sum of the thicknesses of the first, second and third sacrificial layers, a second gap size (or “mid gap”) equal to about a sum of the thicknesses of the second and third sacrificial layers, and a third gap size (or “low gap”) equal to about the thickness of the third sacrificial layer. For an interferometric modulator array, a high gap can correspond to a high gap pixel, a mid gap can correspond to a mid gap pixel, and a low gap can correspond to a low gap pixel. Each of these pixels that are configured with different gap size can produce a different reflected color. Accordingly, such pixels may be referred to herein as high, mid, or low gap pixels.

In some implementations, the plurality of sacrificial layers over the optical stack 1600 may be formed as follows. A sacrificial material can be deposited and etched to result in a first sacrificial layer 144 over what will result in a high gap area 176a. In some implementations, the first sacrificial layer 144 includes a Mo layer having a thickness in the range of about 200-1,000 Å, for example, about 550 Å.

A second sacrificial layer 145 can be deposited and etched to result in a second sacrificial layer 145 over the high gap area 176a and over what will result in a mid gap area 176b. Thus, the second sacrificial layer 145 can be provided over the first sacrificial layer 144 in the high gap area 176a. In some implementations, the second sacrificial layer 145 includes a Mo layer having a thickness in the range of about 200-1,000 Å, for example, about 400 Å.

A third sacrificial layer 146 can be deposited and etched to result in a third sacrificial layer 146 over the high gap area 176a, the mid gap area 176b, and what will result in a low gap area 176c. Thus, the third sacrificial layer 146 can be provided over the first and second sacrificial layers 144-145 in the high gap area 176a and over the second sacrificial layer 145 in the mid gap area. In some implementations, the third sacrificial layer 146 includes a Mo layer having a thickness on the range of about 600-2,000 Å, for example, about 1,350 Å. The etching process to remove the Mo can include Cl₂ and/or O₂.

Although FIG. 13I is illustrated for a configuration in which the second sacrificial layer 145 is provided over the first sacrificial layer 144 and the third sacrificial layer 146 is provided over the first and second sacrificial layers 144, 145, persons of ordinary skill in the art will appreciate that other configurations are possible. For example, the first, second and third sacrificial layers 144-146 need not overlap, and more or fewer sacrificial layers can be formed to provide desired gap sizes.

In FIG. 13J, the process continues by providing a reflective layer 1400a and a support layer 1400b of what will be part of a mechanical layer anchored over the optical stack 16. The reflective layer 1400a can be a variety of metallic materials including, for example, aluminum alloys. In some implementations, the reflective layer 1400a includes aluminum-copper (AlCu) having copper by weight in the range of about 0.3% to 1.0%, for example, about 0.5%. The reflective layer 1400a can be any suitable thickness. In some implementations, the reflective layer 1400a includes an AlCu layer having a thickness in the range of about 200-500 Å, for example, about 300 Å.

Continuing with FIG. 13J, the support layer 1400b can be provided over the reflective layer 1400a. The support layer 1400b can be used to assist a photolithography process of reflective layer 1400a by serving as an antireflection layer and/or to aid in obtaining a desired mechanical flexibility of a fully fabricated mechanical layer. The support material can be deposited and etched to result in the support layer 1400b on reflective layer 1400a above optically active sections 175a-175c. In some implementations, the support layer 1400b includes a SiON layer having a thickness in the range of about 50-1,000 Å, for example, about 500 Å. The etching process to remove the SiON can include CF₄ and/or O₂. The metallic material can be etched after etching support layer 1400b to result in the reflective layer 1400a on the sacrificial layers 144-146 and roughly above optically active sections 175a-175c. The etching process to remove the AlCu can include Cl₂ and/or BCl₃.

In FIG. 13K, the process continues by providing an etch-stop layer 154 over the interferometric modulator array with built-in spacers. The etch-stop layer 154 can be employed to protect the layers of the interferometric device from subsequent etching steps. For example, as will be described below, when the sacrificial layers 144-146 are removed to release the mechanical layer, the etch-stop layer 154 can protect support layers from an etchant used to remove the sacrificial layers 144-146. In some implementations, the etch-stop layer 154 includes an AlOₓ layer having a thickness in the range of about 100-300 Å, for example, about 200 Å. Cavities 133 adjacent to the spacer can remain.

In FIG. 13L, the process continues by providing a first support layer 160. The first support layer 160 can aid in anchoring the mechanical layer to the optical stack 16. For example, the first support layer 160 can fill in cavities 133 adjacent to the spacer 100, helping to support and/or secure the mechanical layer above the optical stack 16 after the sacrificial layers 144-146 are removed and the mechanical layer is released. The first support layer 160 also can increase the height above the spacers 100.

The first support layer 160 can be formed with a dielectric material such as SiON or any other dielectric material well known in the art. The dielectric material can be deposited and etched to remove the first support layer 160 in areas roughly disposed above high gap area 176a and mid gap area 176b. The first support layer 160 deposited on the etch stop layer 154 can remain over the low gap area 176c to form a portion of the completed mechanical layer over the low gap area 176c. In some implementations, the first support layer 160 includes a SiON layer having a thickness in the range of about 1,000-5,000 Å, for example, about 3,000 Å. The etching process to remove the SiON can include CF₄ and/or O₂.

In FIG. 13M, the process continues by providing a second support layer 161. The second support layer 161 can further aid in anchoring the mechanical layer to the optical stack 16. For example, the second support layer 161 can further fill in cavities 133 adjacent to the spacer 100, helping to support and/or secure the mechanical layer above the optical stack 16 after the sacrificial layers 144-146 are removed and the mechanical layer is released. The second support layer 161 also can increase the height above the spacers 100. The second support layer 161 can be formed with a dielectric material such as SiON or any other dielectric material well known in the art. The dielectric material can be deposited and etched to remove the second support layer 161 in areas roughly disposed above high gap area 176a.

The second support layer 161 can remain over the low gap area 176c and the mid gap area 176b. For example, the second support layer 161 can be provided on the first support layer 160 in areas over the low gap area 176c to form a portion of the completed mechanical layer over the low gap area 176c and the second support layer 161 can remain on the etch stop layer 154 in areas over the mid gap area 176b to form a portion of the completed mechanical layer over the mid gap area 176b. In some implementations, the second support layer 161 includes a SiON layer having a thickness in the range of about 1,000-5,000 Å, for example, about 2,600 Å. The etching process to remove the SiON can include CF₄ and/or O₂.

In FIG. 13N, the process continues by providing a third support layer 162. The third support layer 162 can further aid in anchoring the mechanical layer to the optical stack 16 and can further increase the height above the spacers 100. The third support layer 162 can be formed with a dielectric material such as SiON or any other dielectric material well known in the art. The dielectric material can be deposited and etched to provide the desired structure.

For example, the third support layer 162 can remain over the low gap area 176c, the mid gap area 176b, and the high gap area 176a. The third support layer 162 can be provided on the second support layer 161 in areas over the low gap area 176c and on the second support layer in areas over the mid gap area 176b to form a portion of the completed mechanical layer over the low gap area 176c and mid gap area 176b. The third support layer 162 can be provided on the etch-stop layer 154 in the area over the high gap area 176c to form a portion of the completed mechanical layer over the high gap area 176a. In some implementations, the third support layer 162 includes a SiON layer having a thickness in the range of about 500-1,000 Å, for example, about 700 Å. The etching process to remove the SiON can include CF₄ and/or O₂.

The first, second and third support layers 160-162 can be formed with dielectric materials having varying stiffness. The first, second and third support layers 160-162 can have varied thickness or be of a uniform thickness. In some implementations, the thickness of the first, second and third supporting layers 160-162 can each be in the range of about 600-3,000 Å, for example, each about 1,000 Å.

The first, second, and third support layers 160-162 can be used for a variety of functions. For example, the first, second, and third support layers 160-162 can be used to form support structures, including posts and/or rivets. Furthermore, the first, second, and third support layers 160-162 can be incorporated into all or part of the mechanical layer to aid in achieving a structural rigidity corresponding to a desired actuation voltage and/or to aid in obtaining a self-supporting mechanical layer.

As illustrated in FIG. 13N, a portion 161a of the second support layer 161 can serve as part of a support post for a pixel, while another portion 161b of the second support layer 161 can be included in the mechanical layer over the low gap area 176c. By employing the first, second and third support layers 160-162 to serve a variety of functions across pixels of varying gap heights, flexibility in the design of the interferometric device can be improved. In some implementations, the mechanical layer can be self-supporting over certain pixels and can be supported by a support post or other structures over other pixels.

Further, as illustrated in FIG. 13N, the thickness of the mechanical layer formed above the sacrificial layers can be varied by selectively including the first, second and third support layers 160-162 in the mechanical layer over various pixels of the array. For example, the third support layer 162 can be provided over high gap, mid gap and low gap pixels, the second support layer 161 can be provided over mid and low gap pixels, and the first support layer 160 can be provided over low gap pixels. By varying the thickness of the mechanical layer across pixels of different gap heights, the desired stiffness of the mechanical layer can be achieved for each gap height, which can aid in permitting the same pixel actuation voltage for different sized air-gaps for color display applications.

Continuing with FIG. 13N, by forming first, second and third support layers 160-162 over the spacers 100, the height over the spacers 100 may be increased. Thus, the layering method disclosed herein allows for the highest point t_{T} of the interferometric modulator to be the over the spacers 100. As such, these high sections 180 may contact a backplate (not shown) positioned over the interferometric modulator formed on the substrate 20. Accordingly, the spacer structures 100 protect a backplate from contacting the more fragile sections of the mechanical layer; particularly the movable sections of the mechanical layer after the sacrificial layers 144-146 are removed.

In FIG. 13O, the process continues by providing a cap layer 1400c and a hard mask layer 147. The cap layer 1400c can be provided over the supporting layers 160-162 and can have a pattern similar to that of the reflective layer 1400a. Patterning the cap layer 1400c similar to that of the reflective layer 1400a can aid in balancing stresses in the mechanical layer. By balancing stresses in the mechanical layer, the shaping and curvature of the mechanical layer upon removal of the sacrificial layers 144-146 can be controlled. Furthermore, balanced stresses in the mechanical layer can reduce the sensitivity of gap height of a released interferometric modulator to temperature. In some implementations, providing the cap layer 1400c can form a completed mechanical layer.

The cap layer 1400c can be formed with a metallic material such AlCu or any other metallic material well known in the art. In some implementations, the cap layer 1400c is formed with the same material as the reflective layer 1400a. In some implementations, the cap layer 1400c includes AlCu having copper by weight in the range of about 0.3% to 1.0%, for example, about 0.5%. The metallic material can be deposited on the third support layer 162 and etched to remove all but cap layer sections 154a-154c in areas roughly above optically active sections 175a-175c. In some implementations, the cap layer 1400c includes an AlCu layer having a thickness in the range of about 200-500 Å, for example, about 300 Å. The etching process to remove the AlCu can include Cl₂ and/or BCl₃.

Continuing with FIG. 13O, a hard mask layer 147 is provided over the cap layer 1400c. The hard mask layer can act as an anti-reflection layer in aid of the photolithography process when patterning the cap layer 1400c. The hard mask layer 147 may include Mo or a-Si or any other well known materials which can be removed during the sacrificial layer removal process, such as, for example, a XeF₂ release process. The hard mask pattern can be deposited and etched to result in a hard mask layer 147 on the cap layer 1400c. In some implementations, the hard mask layer 147 includes a Mo layer having a thickness in the range of about 200-1,000 Å, for example, about 500 Å. The etching process to remove the Mo can include Cl₂ and/or O₂. The etching process to remove the AlCu can include Cl₂ and/or BCl₃.

In FIG. 13P, the process continues by removing the sacrificial layers 144-146 and hard mask layer 147. In some implementations, the sacrificial layers 144-146 and hard mask layer 147 are removed by exposing the sacrificial layers 144-146 and hard mask layer 147 to vapors derived from solid XeF₂. The sacrificial layers 144-146 and hard mask layer 147 can be exposed for a period of time that is effective to remove the material, typically selectively relative to the structures surrounding the gaps 19a-19c. Other selective etching methods can be used, for example, wet etching and/or plasma etching.

The etch-stop layer 154 can protect the first support layer 160 from the sacrificial release chemistry used to remove the sacrificial layers 144-146. This can prevent the first support layer 160 from attack by the release chemistry used to remove the sacrificial layers. The dielectric protection layer 142 can protect layers of the optical stack 1600, such as the dielectric layer 141, from the sacrificial release chemistry used to remove the sacrificial layers 144-146. Inclusion of the dielectric protection layer 142 can aid in reducing or preventing damage to the optical stack during release, thereby improving optical performance.

With continued reference to FIG. 13P, removing the sacrificial layers 144-146, releases the mechanical layers and forms a first or high gap 19a, a second or mid gap 19b, and a third or low gap 19c. Skilled artisans will appreciate that additional steps can be employed before forming first, second and third gaps 19a-19c. For example, sacrificial release holes can be formed in the mechanical layer 14 to aid in removing the sacrificial layers 144-146.

The first, second and third gaps 19a-19c can correspond to cavities that interferometrically enhance different colors. For example, the first, second and third gaps 19a-19c can have heights selected to interferometrically enhance, for example, blue, red, and green, respectively. The first or high gap 19a can be associated with a first or high gap pixel 172a, the second or mid gap 19b can be associated with a second or mid gap pixel 172b, and the third or low gap 19c can be associated with a third or low gap pixel 172c.

In order to permit approximately the same actuation voltage to collapse the mechanical layer for each gap size, the mechanical layer can include different materials, number of layers, or thicknesses over each of the gaps 19a-19c. Thus, as shown in FIG. 13P, a portion of the mechanical layer over the high gap 19a can include the reflective layer 1400a, the support layer 1400b, the etch-stop layer 154, the third support layer 162 and the cap layer 1400c, while a portion of the mechanical layer over the mid gap 19b can further include the second support layer 161. Similarly, in contrast to the portion of the mechanical layer over the high gap 19a, a portion of the mechanical layer over the low gap 19c can further include the first and second support layers 160, 161. Using a plurality of support layers permits approximately the same actuation voltage to collapse the mechanical layer for each gap size.

After removal of the sacrificial layers 144-146, the mechanical layer can become displaced away from the substrate by a launch height and can change shape or curvature at this point for a variety of reasons, such as residual mechanical stresses. As described above, the cap layer 1400c can be used with the reflective layer 1400a to aid in balancing the stresses in the mechanical layer when released. Thus, the cap layer 1400c can have a thickness, composition, and/or stress selected to aid in tuning the launch and curvature of the mechanical layer upon removal of the sacrificial layers 144-146. Additionally, providing the mechanical layer over the shaping structure 126, and particularly over the protrusion 129 of FIG. 13C, a kink 171 is formed in the mechanical layer 14. The geometric features of the kink 171 can be controlled by varying the geometry of the shaping structure 126, thereby controlling the stresses in the mechanical layer. Control of the launch height can allow the selection of a sacrificial layer thickness needed for a particular gap size which is desirable from a fabrication and optical performance standpoint.

Continuing with FIG. 13P, the highest points t_{T} of the interferometric modulator are at high surfaces 180 located over the spacers 100. The mechanical layer, for example, section 178a collapses during actuation. These movable sections are susceptible to damage and remain below the highest point t_{T}. Accordingly, the high sections 180 protect the mechanical layers. The height of sections 180 and 180′ are shown as about the same height, but can include different heights. As also shown in FIG. 13P, spacers 100 need not be included in between every completed pixel. For example, FIG. 13P illustrates a spacer 100 located in between the high gap pixel 172a and mid gap pixel 172b while no spacer is located between the mid gap pixel 172b and the low gap pixel 172c.

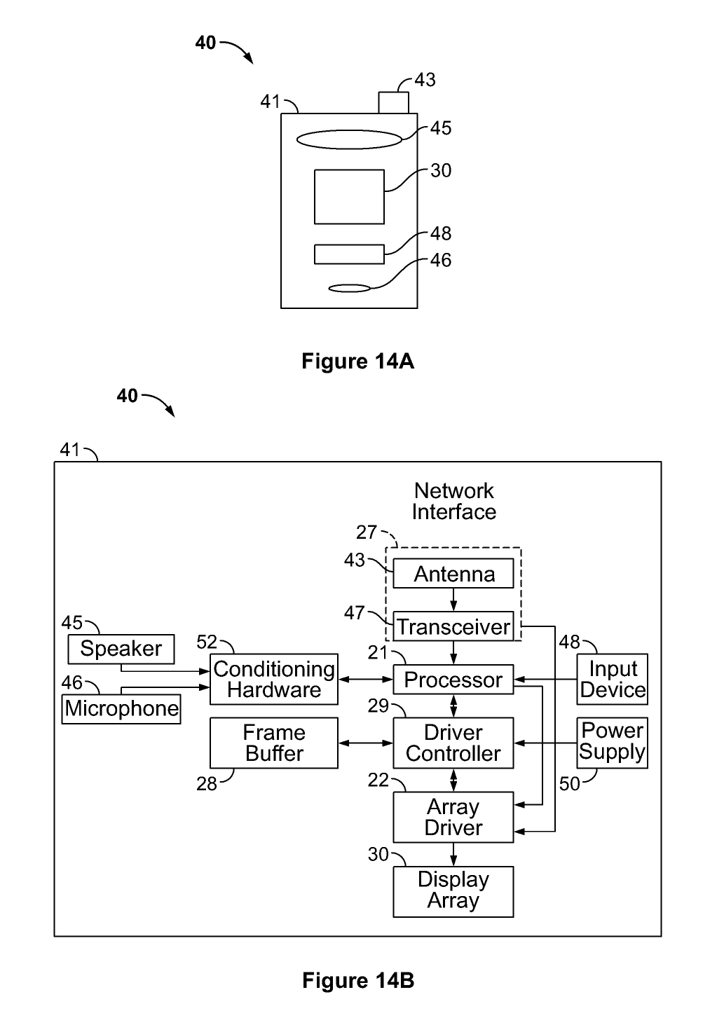

FIGS. 14A and 14B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 14B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system. The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electromechanical device package, comprising:
a substrate;
a plurality of anchor regions disposed on the substrate, wherein the anchor regions include raised spacers;
a plurality of electromechanical devices formed on the substrate, wherein the electromechanical devices are formed over the raised spacers and anchored to the substrate at the anchor regions; and
a backplate sealed to the substrate to form a package, wherein the highest points of the electromechanical devices above the substrate are above the raised spacers.

2. The electromechanical device package of claim 1, wherein the electromechanical devices are interferometric modulators.

3. The electromechanical device package of claim 2, wherein the interferometric modulators have movable mirrors anchored at the anchor regions.

4. The electromechanical device package of claim 1, wherein the spacers are formed over a black mask layer in the anchor region.

5. The electromechanical device package of claim 4, wherein the black mask layer is electrically conductive.

6. The electromechanical device package of claim 1, wherein the raised spacers are dielectric spacers.

7. The electromechanical device package of claim 6, wherein the raised spacers have a height of about 7,500 Å and a diameter of about 1.5 μm.

8. The electromechanical device package of claim 1, wherein the substrate is a transparent substrate.

9. The electromechanical device package of claim 1, wherein the backplate is hermetically sealed to the substrate.

10. The electromechanical device package of claim 1, further comprising:
a display;
a processor that is configured to communicate with the display, the processor being configured to process image data; and
a memory device that is configured to communicate with the processor.

11. The electromechanical device package of claim 10, further comprising:
a driver circuit configured to send at least one signal to the display.

12. The electromechanical device package of claim 11, further comprising:
a controller configured to send at least a portion of the image data to the driver circuit.

13. The electromechanical device package of claim 10, further comprising:
an image source module configured to send the image data to the processor.

14. The electromechanical device package of claim 13, wherein the image source module includes at least one of a receiver, transceiver, and transmitter.

15. The electromechanical device package of claim 10, further comprising:
an input device configured to receive input data and to communicate the input data to the processor.

16. An electromechanical device, comprising:
a substrate;
an anchor region formed on the substrate;
means for spacing the anchoring means from the substrate; and
a movable layer formed over the spacing means and anchored to the anchor region.

17. The electromechanical device of claim 16, wherein the means for spacing are formed over a black mask layer in the anchor region.

18. The electromechanical device package of claim 17, wherein the black mask layer is electrically conductive.

19. The electromechanical device of claim 16, wherein the means for spacing includes raised dielectric structures.

20. The electromechanical device of claim 16, wherein a high point above the substrate is formed above the means for spacing.

21. A method of fabricating an electromechanical system device, comprising:
providing a substrate;
forming an anchor region on the substrate;
forming a spacer on the anchor region; and
forming an electromechanical device anchored to the spacer in the anchor region, wherein the electromechanical device is formed after forming the spacer.

22. The method of claim 21, wherein the spacer is a dielectric spacer.

23. The method of claim 21, wherein the anchor region includes a black mask layer.

24. The method of claim 21, wherein the electromechanical system device is an interferometric modulator device.

25. The method of claim 21, wherein the substrate is a transparent substrate.

26. The method of claim 21, wherein a highest point of the electromechanical device relative to the substrate is located above the spacer.
